(19) United States
(12) Patent Application Publication
(10) Pub. No.: US 2014/0062517 A1
(43) Pub. Date: Mar. 6, 2014

(54) PROBE CARD, TEST METHOD FOR IMAGING ELEMENT AND TEST APPARATUS

(71) Applicant: KABUSHIKI KAISHA TOSHIBA, Tokyo (JP)

(72) Inventor: Tamotsu HARADA, Hiratsuka-Shi (JP)

(73) Assignee: KABUSHIKI KAISHA TOSHIBA, Tokyo (JP)

(21) Appl. No.: 13/764,550

(22) Filed: Feb. 11, 2013

(30) Foreign Application Priority Data
Sep. 4, 2012 (JP) 2012-194092

(51) Int. Cl. G01R 1/073; G01R 31/26

(52) U.S. Cl. CPC G01R 1/073; G01R 31/2601
USPC 324/754.03; 324/755.01; 324/756.03

(57) ABSTRACT

In accordance with an embodiment, a probe card includes a substrate, a first probe and a second probe. The substrate includes a first area and a second area adjacent to the first area. In the first area a first opening is provided. The first probe is provided in the first area. An end of the first probe extends into the first opening. The second probe is provided in the second area.

### CROSS REFERENCE TO RELATED APPLICATIONS

This application is based upon and claims the benefit of priority from the prior Japanese Patent Application No. 2012-194092, filed on Sep. 4, 2012, the entire contents of which are incorporated herein by reference.

### FIELD

Embodiments described herein relate generally to a probe card, a test method for an imaging element, and a test apparatus.

### BACKGROUND

As tests for an imaging device, e.g., an image sensor, there are a bright-period test that is conducted in a state where a chip provided on a substrate is irradiated with light and a dark-period test that is conducted in a state where the chip is shielded from the light.

In recent years, with an increase in number of pixels of the image sensor, an increase in size of the chip advances. On the other hand, to improve a throughput of a test, an increase in number of multiple probe pairs is necessary, but increasing the number of multiple probe pairs is difficult because, for example, an irradiation area of a light source is restricted due to an increase in size of the chip.

### BRIEF DESCRIPTION OF THE DRAWINGS

In the accompanying drawings,

FIG. 1 is a block diagram showing an outline configuration of a test apparatus according to a first embodiment;

FIGS. 2A to 2C are explanatory views of a probe card according to the first embodiment;

FIGS. 3A and 3B are explanatory views of a light shielding member included in the probe card depicted in FIGS. 2A to 2C;

FIG. 4 is an explanatory view of a function of the light shielding member depicted in FIGS. 3A and 3B;

FIG. 5 is an explanatory view of a test method for an imaging element according to the first embodiment;

FIG. 6 is an explanatory view of a test method for an imaging element according to a second embodiment;

FIG. 7 is an explanatory view of a test method for an imaging element according to a reference example;

FIG. 8 is a block diagram showing an outline configuration of a test apparatus according to the second embodiment; and

FIG. 9 is an explanatory view of a probe card according to the second embodiment.

### DETAILED DESCRIPTION

In accordance with an embodiment, a probe card includes a substrate, a first probe and a second probe. The substrate includes a first area and a second area adjacent to the first area. In the first area a first opening is provided. The first probe is provided in the first area. An end of the first probe extends into the first opening. The second probe is provided in the second area.

Embodiments will now be explained with reference to the accompanying drawings. Like components are provided with like reference signs throughout the drawings and repeated descriptions thereof are appropriately omitted.

### (1) First Embodiment of Test Apparatus

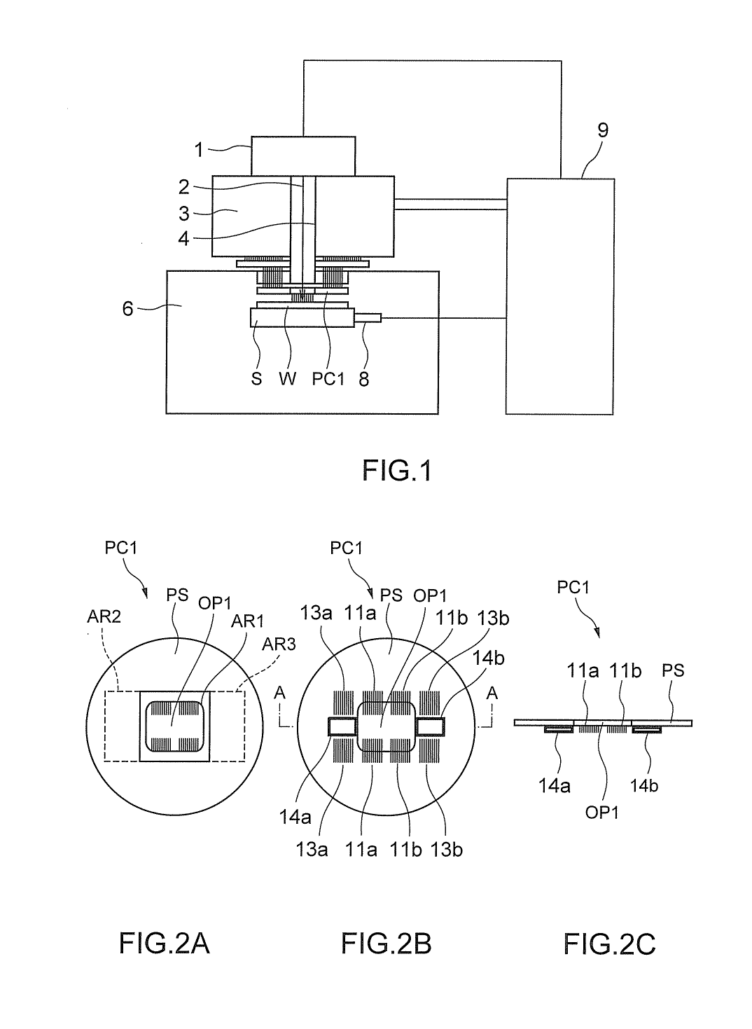

FIG. 1 is a block diagram showing an outline configuration of a test apparatus according to a first embodiment. The test apparatus shown in FIG. 1 includes a tester main body 9, a prober 6, a test head 3, a probe card PC1, a light source 1, and a column 4.

The tester main body 9 is connected to the light source 1, the test head 3, and an actuator 8, generates an instruction signal, supplies this signal to each of the light source 1 and the actuator 8, and controls progressions of a bright-period test and a dark-period test which will be described later. In this embodiment, the tester main body 9 corresponds to, e.g., a control unit.

The prober 6 includes a stage S, a carrier unit (not shown) that carries a wafer W onto the stage S, and the actuator 8.

The stage S holds the water W having imaging devices as test objects arranged on a main surface thereof in such a manner that the imaging apparatuses form a matrix. The stage S corresponds to, e.g., a support unit in this embodiment.

The wafer W corresponds to, e.g., a substrate in this embodiment.

The actuator 8 receives the instruction signal from the tester main body 9, moves the stage S on a horizontal surface parallel to the main surface of the stage S based on this instruction signal, and performs an alignment between an arbitrary chip 12 (see FIGS. 2A to 2C) on the wafer W and the probe card PC1.

The light source 1 generates light 2 in accordance with the instruction signal from the tester main body 9 and irradiates the imaging device of the chip 12 (see FIG. 4) on the wafer W with the light.

The column 4 is provided to pierce through a central part of the test head 3 and controls a light path of the light 2 so that the light 2 from the light source 1 can be applied to the imaging device with a focus thereon.

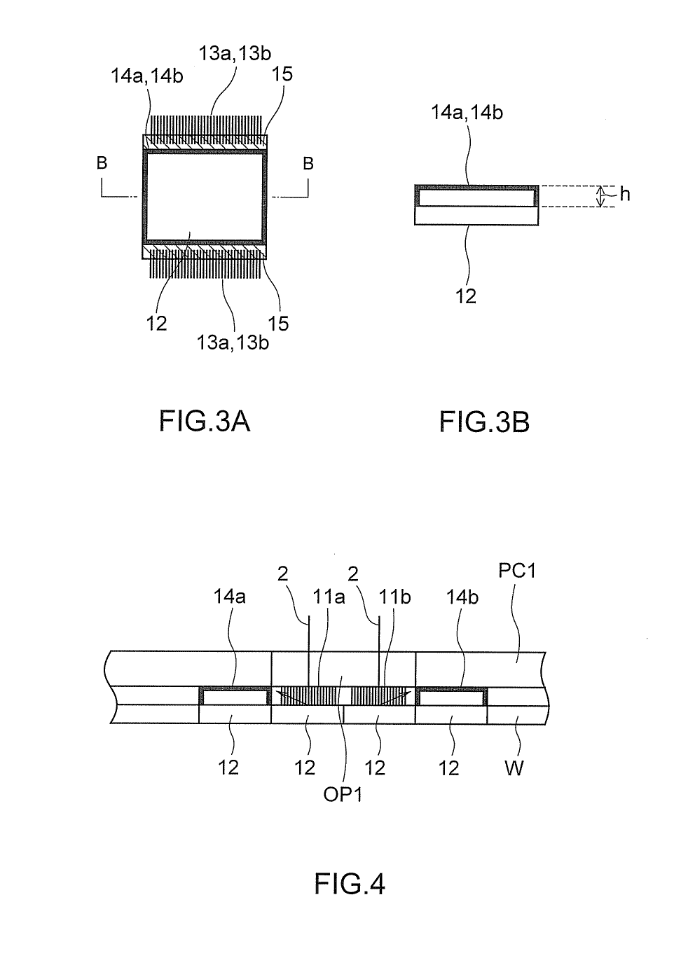

The probe card PC1 includes a plurality of probes (see FIGS. 3A and 3B) that can come into contact with I/O portions of the chip, detects a signal of the imaging device fed from each I/O portion 15 of the imaging device in each of the bright-period test and the dark-period test, and supplies the detected signal to the test head 3.

The test head 3 is connected to the tester main body 9 and the probe card PC1 and conducts each of the bright-period test and the dark-period test with respect to the imaging device based on the instruction signal from the tester main body 9.

### (2) First Embodiment of Probe Card

FIGS. 2A to 2C are explanatory views of the probe card PC1, where FIG. 2A is a top view of the probe card PC1, FIG. 2B is a bottom view of the probe card PC1, and FIG. 2C is a cross-sectional view taken along a line A-A in FIG. 2B.

As shown in FIG. 2A, in a probing area AR1 placed at a substantially central part of a probe card substrate PS, there is provided an opening OP1 that allows the light 2 from the light source 1 to be transmitted therethrough and applied to the chip 12 on the wafer W.

A first characteristics of the probe card PC1 according to this embodiment lies in that probing areas AR2 and AR3 are additionally set so as to sandwich the probing area AR1 therebetween and probes are provided not only in the probing area AR1 through which the light 2 passes but also in the probing areas AR2 and AR3 adjacent to the probing area AR1.

Specifically, as shown in FIG. 2B, on a back surface side of the probe card substrate PS, two pairs of probes 11a and 11b which are arranged at predetermined intervals are provided in the probing area AR1, one pair of probes 13a are provided in the probing area AR2, and one pair of probes 13b are provided in the probing area AR3. The probe pairs 11a and 11b in the probing area AR1 are constituted of a plurality of probe needles that are arranged in such a manner that their respective ends face each other to sandwich a space in the opening OP1 therebetween. The probe pairs 13a and 13b in the probing areas AR2 and AR3 are constituted of a plurality of probe needles that are arranged in such a manner that their respective ends face each other to sandwich a space immediately below the probe card substrate PS therebetween. Furthermore, these probe needles are designed and arranged in such a manner that all of their ends are in contact with and can be connected with the I/O portions 15 of the chip 12 (see FIG. 3A and FIG. 3B). In this embodiment, the probing areas AR1 to AR3 correspond to, e.g., first to third areas, the probe pairs 11a and 11b correspond to, e.g., first probe pairs, and the probe pairs 13a and 13b correspond to, e.g., second and third probe pairs, respectively.

A second characteristic of the probe card PC1 according to this embodiment lies in that the probe card PC1 further includes light shielding members 14a and 14b that block the light 2 that enters the probing areas AR2 and AR3 on the back surface of the probe card substrate PS from the opening OP1 and holds a preferred state during the dark-period test to the chip 12 immediately below the probing areas AR2 and AR3.

FIG. 3A and FIG. 3B are explanatory views of the light shielding members 14a and 14b, where FIG. 3A is a top view seen from a bottom surface side of the probe card substrate PS and FIG. 3B is a cross-sectional view taken along B-B in FIG. 3A. As shown in FIG. 3A, each of the light shielding members 14a and 14b is a tray-like member having a rectangular bottom plate and a frame body integrally formed, and it has a size that enables covering a substantially entire region of the chip 12 excluding each I/O portion 15 with the frame body portion. Each of the light shielding members 14a and 14b is made of a soft material that does not allow the light 2 to pass therethrough, e.g., rubber. A height h of each of the light shielding member 14a and 14b corresponds to a value obtained by adding a predetermined margin to a height of the probe needles during probing, and it is previously adjusted so as to enable close contact with the chip 12 at the time of probing.

As shown in FIG. 4, since the light shielding members 14a and 14b are provided, the light 2 emitted from the light source 1 is prevented from entering the chip 12 placed in each of the probing areas AR2 and AR3 while the bright-period test is being conducted in the probing area AR1. As a result, the probing areas AR2 and AR3 can be used as areas for the dark-period test using the probes 13a and 13b (placed on the inner side or the near side in the vertical direction on the paper in FIG. 4). Furthermore, since the dark-period test can be simultaneously conducted in the probing areas AR2 and AR3 while the bright-period test is being conducted in the probing area AR1, it is possible to simultaneously conduct the dark-period test parallel to the bright-period test in the probing areas AR1 to AR3.

### (3) First Embodiment of Test Method

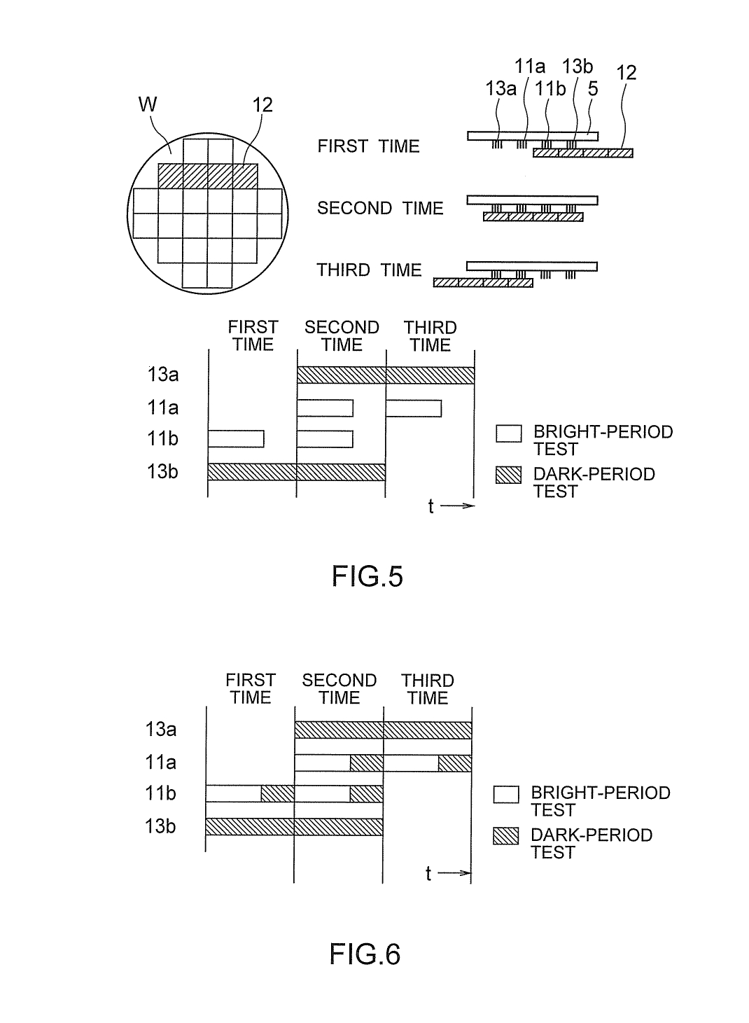

FIG. 5 is an explanatory view of a test method for an imaging element using the probe cared PC1 shown in FIGS. 2A to 2C. In FIG. 5, for ease of explanation, it is assumed that a total of 24 chips are formed in six horizontal rows on the wafer W. The probe cared PC1 has a four probe pair arrangement in which a total of four probe pairs, i.e., one pair (the probing area AR2)+two pairs (the probing areas AR1)+one pair (the probing area AR3) are provided. Thus, the bright-period test is conducted with use of the probe pairs 11a and 11b, and the dark-period test is conducted with use of the probe pairs 13a and 13b, whereby the bright-period test and the dark-period test can be completed with respect to any chip four shaded chips 12 in one horizontal row on the wafer W in FIG. 5 in the test performed for three times.

Specifically, the bright-period test is conducted with the probe pair 11b and the dark-period test is performed with respect to the probe pair 13 in the first test, the bright-period test is carried out with the probe pairs 11a and 11b and the dark-period test is conducted with the probe pairs 13a and 13b in the second time. Moreover, the bright-period test can be conducted with the probe pair 11a and the dark-period test can be conducted with the probe pair 13a in the third test.

Additionally, in case of conducting all the tests for a total of 24 chips 12 arranged in the six horizontal rows, the test must be performed for 12 times+6 times=18 times. However, since a time of the single test is a time that coincides with a longer test of the bright-period test and the dark-period test, if a time required for the bright-period test is 15 seconds and a time required for the bright-period is 20 seconds, a time required for all the tests for the wafer W is 20 seconds×18 times=360 seconds.

### (4) Second Embodiment of Test Method

In the test apparatus shown in FIG. 1, the dark-period test can be carried out in succession to the bright-period test with respect to the probing area AR1 of the probe card PC1 by switching the light source 1 from the ON state to the OFF state, or by blocking the light 2 in front of the probe card PC1 with the use of a non-illustrated shutter under control of the tester main body 9. That is, the probing area AR1 can be used as an area for the bright-period test and the dark-period test. As a result, if a time required for the dark-period test is longer than a time required for the bright-period test, for example, the dark-period test following the bright-period test can be conducted by using the probes 11a and 11b immediately after finishing the bright-period test using these probes while waiting for the dark-period test using the probes 13a and 13b to be finished. Such a test method utilizing a time lag will now be described as a test method according to a second embodiment.

FIG. 6 is an explanatory view of a test method for an imaging element according to this embodiment. As a test apparatus, the test apparatus shown in FIG. 1 can be used as it is.

At the first time, a bright-period test is conducted with use of probe pairs 11b, and a dark-period test is conducted with use of a probe pair 13b, but the operation is rapidly changed to the dark-period test using the probe pair 11b immediately after end of the bright-period test, and the dark-period time is continuously performed.

At the second time, likewise, although the bright-period test using probe pairs 11a and 11b and the dark-period test using probe pairs 13a and 13b are started, the operation is changed to the dark-period test using the probe pairs 11a and 11b immediately after end of the bright-period test.

Moreover, also at the third time, the bright-period test using probe pair 11a and the dark-period test using probe pair 13a are started, and then the operation is changed to the dark-period test using the probe pair 11a immediately after end of the bright-period test.

Like the first embodiment, when a time required for the bright-period test is 15 seconds and a time required for the dark-period test is 20 seconds, a time required for all chips 12 (a total of 24 arranged in six horizontal rows) on a wafer W shown in FIG. 5 is 17.5 seconds×18 times=315 seconds, and a test time reducing effect can be obtained as compared with the test method according to the first embodiment.

### (5) Reference Example of Test Method

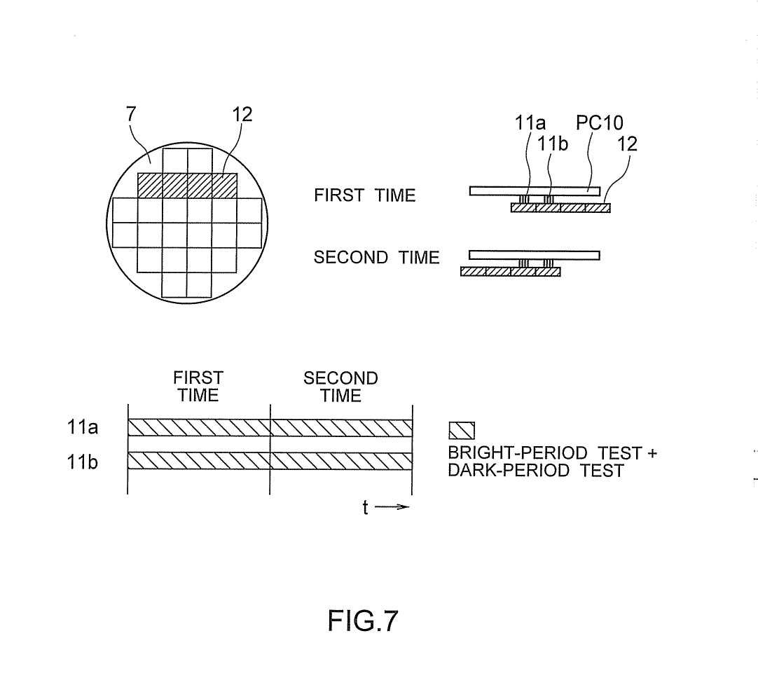

As a comparative example, a test method for an imaging element according to a reference example will now be described with reference to FIG. 7. FIG. 7 shows an example of a method for testing each chip 12 by using a probe card PC10 having a two probe pair arrangement where the probes 11a and 11b are provided only in a probing area having an opening allowing passage of the light provided therein.

In FIG. 7, in order to conduct all tests (the bright-period test+the dark-period test) of four shaded chips 12 in one horizontal row on the wafer W, the tests must be carried out twice. Likewise, in order to conduct all tests for a total of 24 wafers W, the test must be performed for 12 times as shown in the upper right part of FIG. 7. Like the foregoing embodiment, assuming that a time required for the bright-period test is 15 seconds and a time required for the dark-period test is 20 seconds, a time required for all the tests for the wafers W is (15 seconds+20 seconds)×12 times=420 seconds.

On the other hand, in the above-described first embodiment, since the probes 13a and 13b provided in the probing areas AR2 and AR3 for the dark-period test are also used, it is possible to realize an improvement in through put that is approximately 1.2-fold of that in the reference example shown in FIG. 7.

Furthermore, in the second embodiment, since the bright-period test and the dark-period test using the probe pairs 11a and 11b are performed in the probing area AR1 in parallel with the dark-period test in each of the probing areas AR2 and AR3, it is possible to realize an improvement in throughput that is approximately 1.3-fold of that in the reference example shown in FIG. 7.

According to the test method for an imaging element of at least one embodiment mentioned above, since the bright-period test and the dark-period test can be executed in parallel with each other, the throughput of the tests can be improved.

### (6) Second Embodiment of Test Apparatus and Probe Card

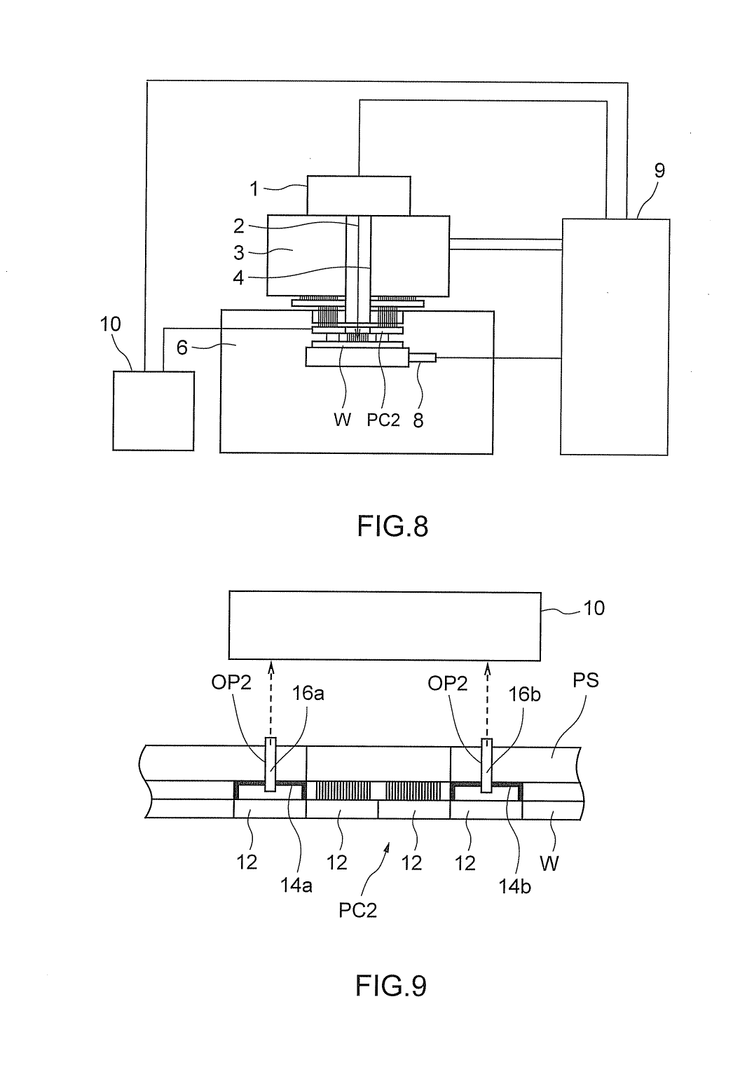

FIG. 8 is a block diagram showing an outline configuration of a test apparatus according to the second embodiment. As obvious from a comparison with FIG. 1, the test apparatus shown in FIG. 8 further includes an exhaust unit in addition to the configuration of the test apparatus according to the first embodiment, and it includes a probe card PC2 connected to the exhaust unit 10 in place of the probe card PC1. As shown in an explanatory view of FIG. 9, the probe card PC2 includes openings OP2 and pipes 16a and 16b provided in the openings OP2. The openings OP2 are pierced in a probe card substrate PS and respective bottom plates of light shielding members 14a and 14b. The pipes 16a and 16b are connected to the exhaust unit 10. Other structures of the probe card PC2 are substantially equal to those in the probe card PC1 shown in FIG. 2A to FIG. 4.

The exhaust unit 10 is also connected to a tester main body 9 and performs vacuum drawing from the pipes 16a and 16b at a time of probing with respect to chips 12 in accordance with a control signal supplied from the tester main body 9. As a result, since adhesion of the light shielding members 14a and 14b and a wafer W is enhanced, light shielding properties in probing areas AR2 and AR3 can be further improved as compared with the foregoing embodiment.

A test method for an imaging device using the test apparatus according to this embodiment including the probe card PC2 shown in FIG. 9 is substantially the same as an example using the test apparatus according to the first embodiment except the vacuum drawing performed by the exhaust unit 10, and hence a specific description will be omitted.

According to the probe card and the test apparatus of at least one of the foregoing embodiments, since the probing area for the dark-period test is additionally provided so as to be adjacent to the probing area in which the opening through which the light passes, the number of multiple probe pairs can be increased, and a throughput of the test can be improved.

Although the several embodiments according to the present invention have been described, these embodiments are presented as examples and not intended to restrict the scope of the present invention.

For example, in the foregoing embodiments, the description has been given as to the example where the two pairs of probes 11a and 11b are provided in the probing area AR1 and the one pair of probes 13a or 13b are provided in each of the probing areas AR2 and AR3, the number of probe pairs is not restricted thereto, and M pairs (M is a natural number that is a multiple of 2) can be provided in the probing area AR1, and (M/2) pairs (M is a natural number that is a multiple of 2) can be provided in each of the probing areas AR2 and AR3. As a specific quantity of M, besides 2 mentioned above, 4 (an 8 probe pair arrangement) or 6 (a 12 probe pair arrangement) can be adopted. Furthermore, in the foregoing embodiments, as the probing areas for the dark-period test, the two probing areas AR2 and AR3 are adopted, but both the probing areas sandwiching the probing area AR1 are not always required, and a single area (either AR2 or AR3) adjacent to the probing area AR1 may be determined as the probing area for the dark-period test. In this case, N pairs (N is a natural number) of probes can be provided to the probing area AR1, and N pairs (N is a natural number) of probes can be provided to one of the probing areas AR2 and AR3. As a specific number of N, e.g., 1 (a 2 probe pair arrangement) or 2 (4 probe pair arrangement) can be adopted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A probe card comprising:
a substrate which comprises a first area and a second area adjacent to the first area, a first opening being provided in the first area;
a first probe in the first area, an end of the first probe extending into the first opening; and
a second probe in the second area.

2. The probe card of claim 1, further comprising a light shielding member which is provided in the second area and blocks light from the first opening.

3. The probe card of claim 2,
wherein the light shielding member comprises a frame body having a shape associated with a peripheral shape of an imaging element which is a test object.

4. The probe card of claim 2,
wherein the frame body has a height associated with a height of the second probe.

5. The probe card of claim 2,
wherein the light shielding member is formed from a soft member which alleviates an impact shock at a time of probing.

6. The probe card of claim 2,
wherein a second opening, is pierced in the substrate to reach a space in the light shielding member; and
the probe card further comprises a pipe which is provided in the second opening and configured to be connected to an external exhauster.

7. The probe card of claim 1,
wherein the first probe is used in both a bright-period test and a dark-period test.

8. The probe card of claim 1,
wherein the second probe is used in the dark-period test.

9. The probe card of claim 1,
wherein the first probe is constituted of N (N is a natural number) probe pairs arranged at predetermined intervals, and each of the first probe pairs is constituted of a plurality of probe needles arranged in such a manner that their respective ends face each other across the space in the first opening,
the second probe is constituted of N second probe pairs which are equal to the N in number and arranged at predetermined intervals, and each of the second probe pairs is constituted of a plurality of probe needles arranged in such a manner that their respective ends face each other across a space immediately below the substrate therebetween.

10. The probe card of claim 1,
wherein the substrate further comprises a third area which faces the second area so as to sandwich the first area therebetween, and
the probe card further comprises a third probe in the third area.

11. The probe car of claim 10,
wherein the third probe is used in the dark-period test.

12. The probe card of claim 10,
wherein the first probe is constituted of M (M is a natural number which is a multiple of 2) first probe pairs arranged at predetermined intervals, and each of the first probe pairs is constituted of a plurality of probe needles arranged in such a manner that their respective ends face each other across a space in the first opening,
the second probe is constituted of half-of-M second probe pairs arranged at predetermined intervals, and each of the second probe pairs is constituted of a plurality of probe needles arranged in such a manner that their respective ends face each other across a space immediately below the substrate, and
the third probe is constituted of half-of-M third probe pairs arranged at predetermined intervals, and each of the third probe pairs is constituted of a plurality of probe needles arranged in such a manner that their respective ends face each other across the space immediately below the substrate.

13. A test method for an imaging element using a probe card comprising a substrate and a first probe, the substrate comprising a first area with a first opening for the first probe and a second area adjacent to the first area, the method comprising:
simultaneously conducting a bright-period test or a dark-period test for an imaging element placed in the first area and the dark-period test for an imaging element placed in the second area,
wherein the probe card further comprises a second probe in the second area and a light shielding member in the second area configured to block light from the first opening.

14. The method of claim 13,
wherein a first time required for the dark-period test is longer than a second time required for the bright-period test, and
the method further comprises conducting the dark-period test for the imaging element placed in the first area for a difference time between the first time and the second time in succession to the second time.

15. The method of claim 13,
wherein a second opening is pierced in the substrate to reach a space in the light shielding member, and
conducting the dark-period test comprises making the space in the light shielding member vacuum.

16. A test apparatus for an imaging element, comprising:
a support unit configured to support a substrate on which imaging elements are provided at predetermined intervals;
a light source configured to irradiate the substrate with light;
a probe card between the support unit and the light sour; and
a control unit configured to conduct tests for the imaging elements,
wherein the probe card comprises:
a substrate which comprises a first area and a second area which is adjacent to the first area, a first opening being provided in the first area to allow the light to pass through the opening;
a first probe in the first area, an end of the first probe extending into the first opening;
a second probe in the second area; and
a light shielding member in the second area configured to block the light from the first opening.

17. The apparatus of claim 16,
wherein the control unit simultaneously conducts a bright-period test for the image element placed in the first area and a dark-period test for the imaging element placed in the second area.

18. The apparatus of claim 17,
wherein a first time required for the dark-period test is longer than a second time required for the bright-period test, and
the control unit conducts the dark-period test for the imaging element placed in the first area for a difference time between the first time and the second time in succession to the second time.

19. The apparatus of claim 16,
wherein the control unit simultaneously conducts the dark-period test for the imaging element placed in the first area and the dark-period test for the imaging element placed in the second area.

20. The apparatus of claim 17,
wherein a second opening is pierced in the substrate to reach a space in the light shielding member, and
the apparatus further comprises an exhaust unit configured to make the space in the light shielding member vacuum.
